(19) United States
(12) Patent Application Publication
(10) Pub. No.: US 2006/0021565 A1
(43) Pub. Date: Feb. 2, 2006

(54) GaInP / GaAs / Si triple junction solar cell enabled by wafer bonding and layer transfer

(75) Inventors: James M. Zahler, Pasadena, CA (US); Harry A. Atwater JR., Pasadena, CA (US); Anna Fontcuberta i Morral, Paris (FR)

Correspondence Address: FOLEY AND LARDNER LLP;SUITE 500, 3000 K STREET NW, WASHINGTON, DC, 20007, US

(73) Assignee: AONEX TECHNOLOGIES, INC.

(21) Appl. No.: 11/193,637

(22) Filed: Aug. 1, 2005

Related U.S. Application Data
(60) Provisional application No. 60/592,670, filed on Jul. 30, 2004.

(51) Int. Cl. C30B 23/00; C30B 25/00; C30B 28/12; C30B 28/14

(52) U.S. Cl. 117/89; 117/92

(57) ABSTRACT

A multi-junction solar cell includes a silicon solar subcell, a GaInP solar subcell, and a GaAs solar subcell located between the silicon solar subcell and the GaInP solar subcell. The GaAs solar subcell is bonded to the silicon solar subcell such that a bonded interface exists between these subcells.

The present application claims benefit of priority of U.S. provisional application Ser. No. 60/592,670, which is incorporated herein by reference it its entirety.

### BACKGROUND OF THE INVENTION

The invention is directed to solar cells, such as triple junction solar cells made by wafer bonding.

Conventional triple-junction solar cells consist of GaInP and GaAs subcells heteroepitaxially grown on a p-type Ge substrate. During the growth process, a third subcell is formed by the near-surface doping of the Ge substrate with As to form an n-p junction. The device structure consists of GaInP, GaAs, and Ge subcells separated by heavily-doped tunnel-junctions to enable efficient electrical contact between the cells (FIG. 1A). It is fortuitous that this material combination not only meets the lattice-matching requirements for heteroepitaxy, but also has reasonable current matching in the subcells, a requirement for efficient two-terminal tandem solar cell. However, there are drawbacks to using a Ge substrate in the fabrication of the device that relate to the mass of the finished structure and the cost of the Ge input material.

### BRIEF DESCRIPTION OF THE DRAWINGS

FIGS. 1A and 1B are side cross sectional views of solar cells according to the prior art and to embodiments of the invention, respectively.

FIG. 2 shows efficiency curves as a function of top subcell bandgap comparing the solar cells of FIGS. 1A and 1B. Efficiency curves are provided for a three junction solar cell with a 1.42 eV center subcell with Ge or Si bottom subcells, respectively, operated at various temperatures under a 1 sun AM0 illumination at a temperature of 200 K.

FIGS. 3-18 show side cross sectional views of steps in methods of making solar cells according to the embodiments of the invention.

### DETAILED DESCRIPTION OF THE PREFERRED EMBODIMENTS

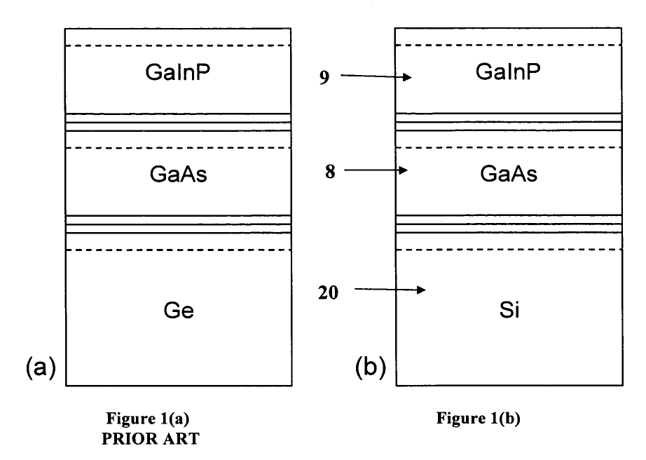

The predominant application for triple-junction solar cells is in space-based applications for satellite power systems. Because of high cost of placing payloads into space, an important design factor for this application is the Watts per kilogram of the final device. The embodiments of the invention describe a solar cell design and associated manufacturing techniques that will increase the Watts per kilogram by a factor of two or more over existing designs. Specifically, the design uses wafer bonding and light ion, such as hydrogen and/or hydrogen and helium, implantation induced layer transfer to integrate an epitaxial template with a silicon support substrate that is designed to act as an active subcell in the triple-junction solar cell structure. The active silicon substrate contains a silicon solar subcell. This template is then used to epitaxially integrate GaAs subcells (which includes InGaAs subcells) and GaInP subcells with the Si subcell, as shown in FIG. 1B. Each subcell of the solar cell contains a p-n or a p-i-n junction of the above named semiconductor material.

Because of its superior mechanical robustness, the thickness of the Si substrate can be reduced significantly (for example to 100 μm) versus the standard thickness of 140 μm for the Ge substrates used in the fabrication of conventional triple-junction solar cells. Additionally, the density of Si, 2.32 g cm⁻³, is less than half of the density of Ge, 5.33 g cm⁻³. When taken together, these two factors reduce the mass of the substrate by a factor of 3.2.

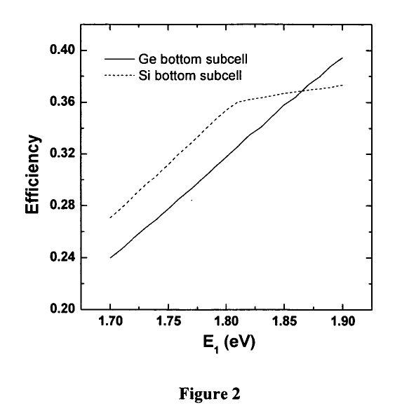

By making the Si support substrate an active component of the solar cell, the overall efficiency can be maintained near the efficiency of a conventional triple-junction solar cell as indicated by detailed balance calculations of the thermodynamic limiting efficiency of such cells operated under 1 sun AM0 conditions (FIG. 2). These calculations summarize the effect of the bandgap of the top GaInP subcell (E₁) on the efficiency of the triple-junction cell design.

At lower top cell bandgaps, the GaAs subcell is the current limiting component of the cell and the increased operating voltage of the Si subcell allows the cell to operate at roughly 3% higher efficiency. For top cells with a top subcell bandgap above 1.8 eV, the Si subcell becomes the current limiting cell and the GaInP/GaAs/Si cell structure has a theoretical limiting efficiency 2% less than the conventional cell by the time the top subcell bandgap reaches 1.9 eV. However, due to the development of single-junction Si solar cells, the practical efficiency of the active Si triple-junction solar cell could be higher for all values of the top subcell bandgap in a real cell structure. Additionally the weight performance of the proposed cell is compelling even in the possible event of the loss of 2% absolute efficiency.

The multi-junction solar cell includes a wafer-bonded GaInP/GaAs/Si triple-junction solar cell that increases the W/kg of the solar cell. The use of wafer bonding to incorporate the III/V subcells consisting of GaInP and GaAs allows this structure to be fabricated without the epitaxial growth of GaAs directly on the Si subcell. This enables misfit dislocations associated with the lattice constant mismatch between GaAs and Si to be avoided by isolating these defects at a bonded interface.

A variety of methods for integrating a GaInP/GaAs photovoltaic structure with an active-Si substrate will be described with respect to the embodiments of the invention. This integration is performed by either bonding and layer transfer of a thin foreign semiconductor film to an active-Si substrate which serves as an epitaxial template for the growth of the GaInP/GaAs photovoltaic structure, or the direct bonding of a completed GaInP/GaAs photovoltaic structure to an active-Si substrate. Additionally, a thin film on the backside of the Si substrate may be used to control the stress and bow of the wafer bonded substrate structure during process steps, such as chemical mechanical planarization, photolithography, and epitaxy.

Methods of Fabrication of the GaInP/GaAs/Si Solar Cell Structure

Wafer bonding is used to integrate the materials in the fabrication of an active Si triple-junction solar cell. This is due to the lattice-mismatch limitations of directly growing GaAs and related III/V semiconductors on a Si substrate with sufficient quality to enable efficient performance of a minority carrier device, such as a solar cell. By utilizing wafer bonding, these dissimilar materials can be brought together without injecting misfit dislocations caused by the lattice mismatch of the materials into the active GaAs and GaInP subcells. There are several methods of fabrication that can be used to manufacture the described active-Si triple-junction solar cell. The first step in all such designs is the fabrication of the Si subcell that will serve as the mechanical substrate for the finished structure.

Active-Si Subcell/Mechanical Substrate Fabrication

The conventional design of a triple-junction solar cell utilizes an “n-on-p” doping configuration for two reasons. First, the diffusion of As into the Ge substrate during GaAs growth leads to the formation of an n-p junction in this design. Also, this design employs a thin n-type emitter that creates the built-in field that provides the driving force for the separation of electron-hole pairs created by photon absorption. Thus, the minority carriers that contribute most of the current are electrons in the p-type region. Generally, electrons have longer lifetimes and greater mobilities than holes, which would be the collected minority carriers in a “p-on-n” design.

In the case of an active-Si triple-junction solar cell, there are no epitaxial restrictions on the emitter doping. However, the “n-on-p” cell design is desirable due to the minority carrier properties in this structure. The process steps and device characteristics for such a cell are described below, but it is understood that a reciprocal “p-on-n” cell design can be fabricated by reversing the doping scheme described below.

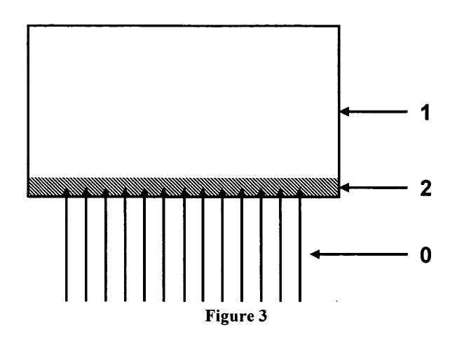

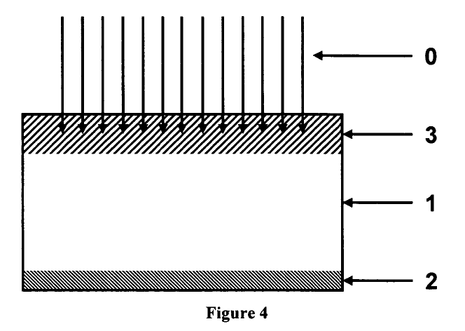

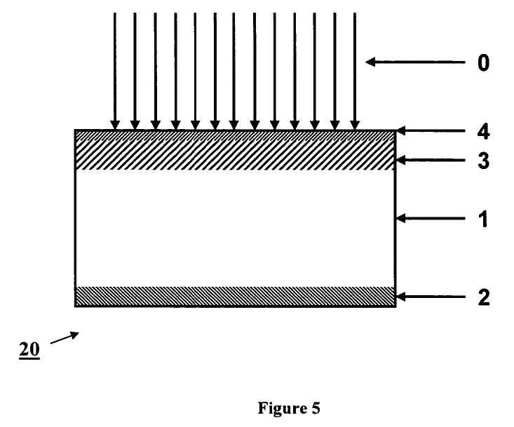

The product characteristics and fabrication process steps that may be used to create the active-Si handle substrate for an “n-on-p” triple-junction solar cell are as follows. A lightly p-doped Si substrate of 100 μm thickness is backside shallow implanted with a p-type dopant such as B or Ga to form a heavily-doped backside contact region upon annealing and dopant activation, as shown in FIG. 3. FIG. 3 shows ion implantation of the backside contact region of a Si substrate 1 with a p-type ion 0 to create a thin, heavily-doped p-type region 2 for making a low-resistance contact to the back surface of Si. The front surface of this substrate is implanted to ˜100 nm with an n-type dopant such as P or As to form an n-type emitter structure, such as a lightly doped emitter structure, upon annealing and dopant activation, as shown in FIG. 4. FIG. 4 shows ion implantation of the front surface of the substrate 1 with n-type ions 0 to create an n-type emitter region 3. The front surface of the Si substrate is further implanted with a heavier peak concentration of an n-type dopant to form a heavily-doped surface region to facilitate electrical contact upon annealing and dopant activation, as shown in FIG. 5. FIG. 5 shows ion implantation of the front surface of the substrate 1 with n-type ions 0 to create a heavily doped n-type contact region 4 above the lightly doped n-type emitter region 3. To ensure heavy doping at the surface, an oxide, such as a silicon oxide layer, can be applied to the front surface of the substrate 1 to allow the range of the implant to be at the Si/oxide interface. This oxide would then be removed prior to bonding of the active-Si handle substrate to the substrate that contributes the wafer bonded and transferred epitaxial template layer. Thus, the silicon p-n solar subcell 20 is formed. This subcell 20 is also referred to herein as the active Si support substrate.

Wafer Bonding and Layer Transfer of a Thin Film Epitaxial Template Layer

There are two primary ways to integrate the III/V semiconductor subcells 8, 9 with the active-Si support substrate 20. The first way is wafer bonding of a thin semiconductor film to the active-Si substrate to serve as a heteroepitaxial template, as will be described with respect to the first and second embodiments. The second way is wafer bonding q finished GaInP/GaAs solar cell structure to the active-Si substrate, as will be described with respect to the third embodiment. Either of these methods can be implemented in multiple ways. The possibilities can be organized as follows.

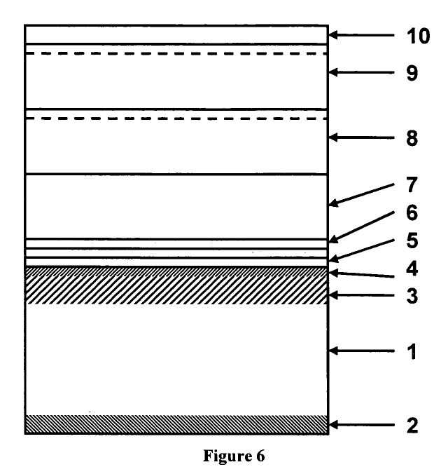

In the first and second embodiments, a bonded transferred thin semiconductor film or layer serves as a heteroepitaxial template for the epitaxial growth of the GaInP/GaAs subcells, as shown in FIG. 6. The bonded transferred layer may comprise a thin Ge film exfoliated from a Ge substrate, as described in the first embodiment. Alternatively, the layer may comprise GaAs layer from a GaAs film on a Ge substrate or from a GaAs substrate, as described in the second embodiment. Specifically, FIG. 6 illustrates a triple junction solar cell fabricated on an active-Si support substrate 20 comprising the backside contact region 2 on the Si base region 1, the n-type Si emitter 3 and the heavily doped contact region 4. The solar cell also comprises the bonded and transferred layer 5, such as the Ge or GaAs layer, the seed layer and tunnel junction in the epitaxial device 6, which are epitaxially grown on layer 5, and the GaAs buffer region 7. The solar cell also comprises the GaAs subcell 8, the GaInP subcell 9 and the top surface window layer 10 which are epitaxially grown over the layer 5. The interface between the heavily doped region 4 and the layer 5 is a bonded region in this structure.

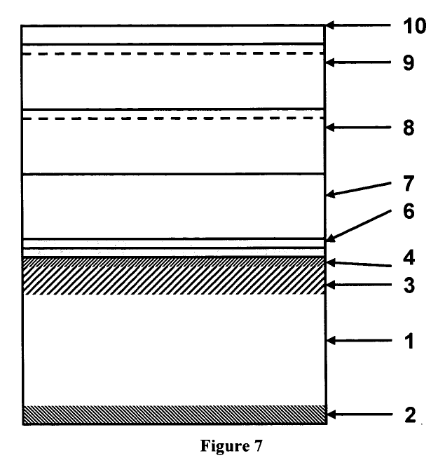

In the third embodiment, a fabricated GaInP/GaAs cell structure is bonded to the active-Si substrate, as shown in FIG. 7. The solar cell may be completed either by light ion implantation, such as H or H/He implantation through a completed GaInP/GaAs cell structure 8, 9 to exfoliate the cell structure from a device substrate, or through fabrication of the GaInP/GaAs cell structure 8, 9 on a surrogate or device substrate that enables liftoff of the structure 8, 9 through a lateral etch process. Specifically, FIG. 7 a shows a completed triple-junction solar cell fabricated on an active-Si support substrate 20 using direct layer bonding and layer transfer of a fully fabricated GaInP/GaAs device structure. The active-Si support substrate 20 contains a backside contact region 2, the Si base region 1, the n-type Si emitter 3 and the heavily doped contact region 4. The solar cell also contains the seed layer and tunnel junction in the epitaxial device 6, the GaAs buffer region 7, the GaAs subcell 8, the GaInP subcell 9 and the top surface window layer 10. The interface between region 4 and tunnel junction/seed layer 6 is a bonded region in this structure.

A bonded interface between the active Si support substrate 20 and the subcells 8, 9 should be an ohmic or low resistance interface, with a low specific-resistance, such as a resistance of 40 ohms per square centimeters or less. This will be achieved by both the type of bonding utilized (either hydrophobic or bonding of extremely thin oxides) and the doping scheme of the bonded film and active-Si handle substrate. As was already described in the fabrication process for an active “n-on-p” Si substrate 20, there will be an extremely thin heavily-doped n-type region 4 at the bonding surface of the active-Si substrate. Additional integration-scheme specific steps will be described for each integration scheme in the first, second and third embodiment sections below.

Bonding and Layer Transfer of a Thin Ge Film to an Active-Si Substrate to Serve as a Heteroepitaxial Template According to a First Embodiment

In the first embodiment, a process similar to the one described in U.S. patent application Ser. No. 10/251,33, filed on Dec. 19, 2002, entitled “Method of Using A Germanium Layer Transfer to Si For Photovoltaic Applications and Heterostructures Made Thereby”, incorporated herein by reference it its entirety, is applied to the bonding and layer transfer of a thin film or layer of Ge to the active-Si substrate. The integration scheme uses an extremely thin Ge film to minimize the band-to-band and free-carrier absorption of photons needed for the generation of photocurrent in the Si subcell. The use of heavily doped material achieves low specific resistance at the bonded interface and provides a large majority carrier density that can lead to reduced transmission.

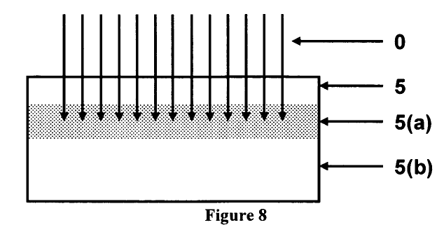

A method for the integration of a GaInP/GaAs cell structure on active-Si in an “n-on-p” doping scheme using a thin Ge heteroepitaxial template of the first embodiment is as follows. A degenerately-doped, n-type Ge substrate is implanted with light gas ions, such as hydrogen and/or helium, to a desired depth and to a total concentration sufficient to allow the exfoliation of a thin film upon annealing, as shown in FIG. 8. FIG. 8 shows ion implantation of a device substrate, such as a Ge substrate 5b with a light gas ions (H⁺ and/or He⁺) 0 to form a damaged region 5a that enables the exfoliation of a thin single-crystal device film 5. For example, helium ions may be implanted first, followed by hydrogen ions which stabilize and passivate the defect structures created by the helium ion implantation. If the doping of the n-type substrate 5b is too low to make low-resistance contact to the Si substrate 1, the use of several shallow implants of As or P can be used to increase the film doping level prior to ion implantation. The use of a surface protective film, such as sputter deposited SiO₂ may be employed to protect the Ge surface from texturing during the implantation process. This protective film would then be removed prior to bonding of the substrates.

The ion implanted Ge substrate and active-Si substrate are then cleaned to remove organic contamination and particulates. A typical, but not limiting process for this might include the following process steps:
a. Ultrasonic cleaning in acetone to remove particulates and organic contamination.
b. Ultrasonic cleaning in methanol to remove particulates and organic contamination.
c. Rinsing in DI water to remove methanol and acetone from steps a and b.
d. Brief etching in dilute hydrofluoric acid to remove any native oxide on the Si and Ge substrates. Other acids may also be used to leave a hydrophobically passivated surface.
e. DI rinsing.
f. Spin drying to remove any water.

The previous process step leaves a clean, relatively hydrophobic surface on each substrate. Bonding can be initiated at this point, or subsequent surface activation with a dry process, such as plasma activation, can be performed to prepare the substrate surfaces for bonding. For plasma activation, process gases include, but are not limited to, N₂, forming gas (H₂/N₂), O₂, and Ar or He for low pressure plasma processes.

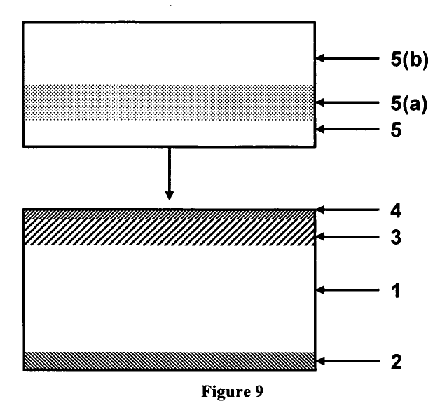

Bonding is initiated by placing the polished, activated substrate surfaces face-to-face and bringing them into contact, as shown in FIG. 9. FIG. 9 shows bond initiation between an implanted device substrate 5b and a fabricated active-Si bottom subcell 20. The subcell 20 contains the p-type Si base region 1, the p+ Si back surface contact region 2, the n-type Si emitter region 3 and the n+ Si bonding contact region 4. The device substrate 5b includes the device film or layer, such as a Ge layer 5, and the implanted or damaged region 5a. Several process parameters can be varied during this process to affect the quality of the bond, such as:
g. Bonding ambient, including but not limited to:
   i. Vacuum;
   ii. Low pressure gases such as H₂/N₂, N₂, Ar, etc.;
   iii. Atmospheric pressure gases such as H₂/N₂, N₂, Ar, etc.
h. Bond initiation temperature as a means of controlling the strain state of the bonded thin film.
i. Center-pin initiation to avoid the capture of gas at the bonded interface by near-simultaneous formation of multiple bonding points between the substrates.
j. Application of uniaxial pressure to ensure intimate contact between the substrates to improve bonding.

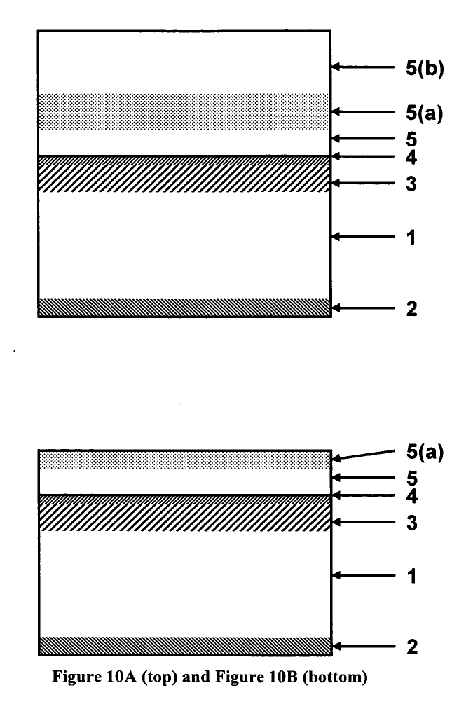

Following bond initiation, layer transfer is accomplished by annealing the substrate 5b to enable the implant induced exfoliation of the thin film. This can be performed with a tailored temperature cycle to ensure optimal bonding and transfer uniformity. Additionally, the application of uniaxial pressure during the transfer process can be used to prevent thermo-mechanical stresses arising in the dissimilar substrate pair form causing debonding or fracture of the bonded pair prior to layer transfer. FIG. 10A shows the bonded structure following the bond initiation process depicted in FIG. 9. FIG. 10B shows the bonded structure following layer exfoliation, where the device substrate 5b and part of the damaged region 5a are exfoliated following an anneal and/or mechanical separation along the damaged region 5a, leaving the device film 5 and a portion of the implant damaged region 5a bonded to the Si subcell 20. The bonded interface is between region 4 and layer 5.

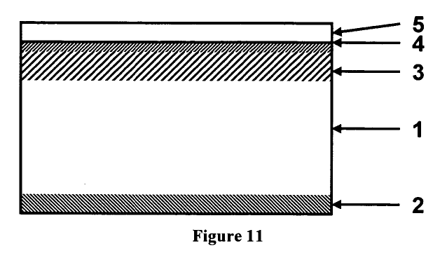

Following exfoliation, a chemical polish or a chemical mechanical polish (CMP) process is utilized to remove the near surface damage from the transferred Ge thin film, as shown in FIG. 11. Additionally, the transferred layer 5 is thinned to enable efficient transmission of photons to the active-Si substrate 20 below. The thinning process can be conducted with a wet etch and/or a CMP process. The wet chemical etch may consist of HF:H₂NO₃:Acetic Acid in varying parts to enable a controlled isotropic etch of Ge. The CMP process may utilize an isotropic etch with a pad or a pad and slurry to provide a mechanical component to the etch process. Surface cleaning following the polish process may be provided to prepare the Ge/Si bonded structure for epitaxial growth of a GaAs/GaInP solar cell structure. This would consist of an acid etch to remove any residual oxide and a clean process designed to remove residual slurry.

Epitaxial growth is then performed on the Ge/Si structure (i.e., the Ge layer 5 on the Si subcell 20 to form a “n-on-p” GaInP/GaAs cell structure. A low-resistance contact of the upper cell structure to the Si subcell is provided by the hydrophobic passivation to form a covalently bonded interface and the heavy doping of the region 4 and layer 5. As described with respect to FIG. 6, above, the bonded device structure contains a heavily-doped, several nm thick n-type GaAs seed layer (shown in FIG. 6 as part of tunnel junction 6). This enables a n-Ge/n-GaAs contact. The heavy doping makes any conduction barrier due to valence band offsets relatively thin to enable tunneling. The n-GaAs/p-GaAs tunnel junction and the GaAs buffer layer 7 can then be grown over the seed layer in the structure to allow dopant switching to p-type to form the GaAs base structure and to reduce defects in the active subcells, respectively. The order of these structures in the fabrication process can be selected for optimal device performance, for instance to minimize free-carrier absorption in the GaAs buffer layer. The “n-on-p” GaAs 8 and GaInP 9 subcell structure can be fabricated on the buffer layer 7/tunnel junction 6 structure just as is done in a conventional triple-junction solar cell structure. This finished structure is then packaged into a space-based solar array using conventional semiconductor device packaging techniques.

Bonding and Layer Transfer of a Thin GaAs Film to an Active-Si Substrate to Serve as a Heteroepitaxial Template Layer of the Second Embodiment

In the second embodiment, the thin, transferred, bonded Ge layer 5 is replaced with a thin, transferred, bonded GaAs layer 5. The rest of the process is similar to that of the first embodiment. The GaAs layer 5 may be exfoliated from a bulk, heavily doped GaAs wafer 5b or it may be exfoliated from a composite device substrate 5b comprising a GaAs film on a Ge substrate, as described in U.S. provisional patent application Ser. No. 60/564,251 filed Apr. 21, 2004 and a counterpart PCT application serial number PCT/US2005/013609 filed Apr. 21, 2005, both titled “A Method for the Fabrication of GaAs-Si Virtual Substrates” and both incorporated herein by reference in their entirety. In either case, the use of a thin GaAs layer or film (rather than Ge) as the epitaxial template mitigates the need to minimize the thickness of the transferred layer since GaAs is an active part of the device. In contrast, the use a Ge film causes a reduction of photocurrent in the Si subcell due to band-to-band absorption, since the bandgap is lower than that of Si. However, the heavy doping of a GaAs transferred layer will still present a risk for free-carrier absorption for thick films.

Wafer bonding and layer transfer of a thin GaAs film to an active-Si substrate from a bulk GaAs substrate involves a process similar to the process of integration of a Ge thin film with an active-Si substrate of the first embodiment. A degenerately-doped n-type GaAs substrate 5b is implanted with a hydrogen and/or helium to a desired depth and total concentration sufficient to allow the exfoliation of a thin film or layer 5 upon annealing using temperature and dose-rate control to enable the exfoliation process to be used in GaAs. The implanted GaAs substrate 5b and active-Si substrate 20 are then cleaned as in the first embodiment, except that hydrochloric acid or another GaAs specific etchant may be necessary to leave a hydrophobic GaAs surface. This etch would be performed on the GaAs substrate only. The rest of the process is the same as in the first embodiment and will not be repeated.

An alternative fabrication method for the GaAs/Si structure that serves as the template for the subsequent growth of the GaInP/GaAs structure is to employ transfer of a GaAs layer 5 from a GaAs/Ge substrate 5b, comprising a GaAs film formed on a Ge substrate. This process enables the ion implantation induced exfoliation process to be performed in a system that has been shown to be more repeatable with wider process windows for the exfoliation process. Furthermore, the growth of GaAs on GaAs is a more robust MOCVD process due to the ease of growing polar-on-polar semiconductors.

The device substrate 5b is formed by a growth of a thin film of n-type doped GaAs structure on a Ge substrate to enable low-resistance electrical contact between the film and the active-Si substrate. The thickness of the layer can be selected to control the thickness of the GaAs epitaxial template film on the active-Si substrate. Implantation of the GaAs/Ge substrate with an optimized dose and energy combination of H⁺ or H⁺/He⁺ forms the damaged region 5a. The implant energy is selected to ensure that the damaged region 5a of the implantation occurs predominantly in the Ge substrate away from the Ge/GaAs interface. The dose at a given energy can be optimized as a function of substrate temperature during implant.

Furthermore, by building an optional etch-stop layer into the epitaxial structure, a clean surface for subsequent epitaxy can be revealed by using a selective etch only. The etch stop layer may be any layer which allows epitaxial growth of the device or transferred layer S over it and which can be selectively etched compared to the device layer 5. When the device substrate 5b is separated, the remaining portions of the damaged region 5a and the device substrate 5b are removed by etching or polishing with a first selected etching or polishing medium which preferentially etches or polishes the device substrate to the etch stop layer. Thus, since the etch stop layer has a lower etching or polishing rate than the device substrate, the etch or polish stops on the etch stop layer. Thereafter, the etch stop layer is selectively removed by etching or polishing by using a second etching or polishing medium which preferentially etches or polishes the etch stop layer compared to the device layer 5. Thus, the removal of the etch stop layer stops on the device layer, thus leaving a smooth, abrupt device layer surface with low damage.

Thus, using a lattice matched etch stop layer, a well-defined surface and thickness can be selected for the transferred GaAs film. For instance, growth of a thin InGaP structure near the bottom of the GaAs on Ge device substrate 5b would allow selective removal of the InGaP with NH₄OH:H₂O₂:H₂O following bonding to leave a smooth, abrupt GaAs surface. Alternatively, growth of a thin AlGaAs structure near the bottom of the GaAs on Ge device substrate 5b could also form a smooth, abrupt etch stop layer that can be selectively removed with a citric-acid:H₂O₂ solution. Otherwise, the method of the second embodiment using a GaAs/Ge device substrate 5b is the same as in the first and second embodiments. If desired, the etch stop layer may be located between the Ge substrate and the GaAs layer.

If the etch stop layer is not present, then material selective chemical mechanical polishing or chemical polishing will be used to remove the Ge film (i.e., the remaining portion of device substrate 5b and damaged region 5a from the GaAs layer 5 leaving a thin, single-crystal GaAs layer 5 bonded to a Si handle substrate 20. The literature reports that modest etch rates can be achieved for germanium using a 30% H₂O₂:H₂O etch composition. This etch forms a stable oxide on GaAs surfaces that prevents further etching. This can be used to remove the residual Ge from the GaAs device film. As described above, further refinement of the device layer thickness can be performed by building in an etch stop structure using AlGaAs or GaInP. The Ge substrate 5b can then be reclaimed by a subsequent wafer repolish. This enables the possibility of transferring many films from a single substrate.

Wafer Bonding and Layer Transfer of a Fully Fabricated Solar Cell Structure to an Active-Si Support Substrate of the Third Embodiment

The previous embodiments described process techniques to integrate a thin Ge or GaAs film onto an active-Si substrate to serve as an epitaxial template for the growth of a subsequent GaInP/GaAs solar cell structure. This method of integration has the merit of simple material integration, but it has the disadvantage of thermal stressing the Ge/Si or GaAs/Si substrate at the processing temperature. Additionally, upon cool down from growth, there will be additional stresses exerted on the Si substrate and grown GaInP/GaAs cell structure due to the thermal mismatch between the Si support and the relaxed film grown at temperatures in the range of 680° C.

The third embodiment describes the integration of finished epitaxial solar cell structures to an active-Si handle substrate. This allows the III/V components of the cell to be fabricated on a substrate that has minimal stress during growth and cool down. Specifically, the third embodiment describes a transfer of a fully fabricated GaInP 9/GaAs 8 upper and middle solar subcells to the active-Si support substrate 20.

One aspect of this embodiment includes growing a GaInP/GaAs solar cell device on a Ge substrate and subsequently implanting light ions to a depth below the active device to enable exfoliation of the device onto an active-Si substrate. As in the previous embodiments, the devices described here are “n-on-p”, but a modified fabrication process could be used to manufacture a “p-on-n” device.

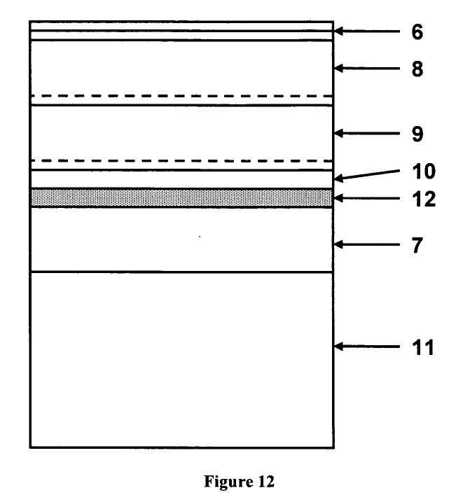

As shown in FIG. 12, a GaInP 9/GaAs 8 tandem solar cell structure is fabricated “upside down” on a Ge substrate 11, with the subcell 9 being located below subcell 8. A nucleation and buffer layer 7, such as a GaAs layer, is grown on substrate 11 to reduce the defects in the epitaxial film. An optional etch-stop layer 12 is then grown to allow controlled removal of the GaAs buffer layer 7 and any material damaged by the implantation. This etch stop layer 12 may be a thin GaInP structure on the GaAs buffer layer, which would allow selective removal of the GaInP with NH₄OH:H₂O₂:H₂O following bonding to leave a smooth, abrupt AlGaInP window layer. Alternatively, the etch stop layer 12 may be a thin AlGaAs structure near the bottom of the GaAs on Ge device, which could also form a smooth, abrupt etch stop layer that can be selectively removed with a citric-acid:H₂O₂ solution.

A conventional GaInP/GaAs subcell design is epitaxially grown over the etch stop layer, with the window layer 10 being grown first, followed by the GaInP subcell 9, followed by the GaAs subcell 8 and ending with the tunnel junction 6 containing an upper thin, highly-doped n-type GaAs layer to serve as a low-resistance contact to the heavily doped n-type surface of the active-Si substrate 20. Following bonding to the active-Si substrate 20 and removal from the Ge substrate 11, the GaInP/GaAs structure is ordered with the GaInP subcell at the top of the tandem structure.

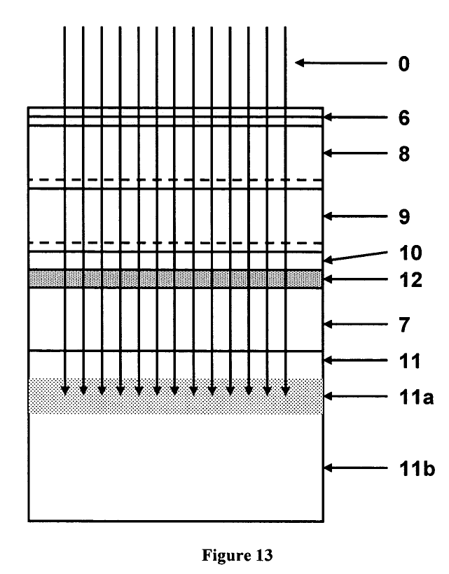

As shown in FIG. 13, after fabrication, the III/V tandem device structure is implanted with H⁺ or He⁺/H⁺ ions to enable exfoliation of the entire structure from substrate 11. This requires an implant with a peak range below the total thickness of the III/V GaInP/GaAs tandem structure. A typical thickness would be 5 μm. There are two means of achieving an implant range beyond this thickness. One means is implantation with a high energy beam which can achieve implantation ranges beyond 5 μm. For H⁺, the implant energy must exceed 600 keV for the implant range to reside in the Ge substrate. For He⁺ the required energy is approximately 2 MeV. Another means is channeled implantation through the <100> or <110> zone axis of a substrate, which can lead to deeper implant ranges by several multiplicative factors. Additionally, the technique reduces damage above the peak range. By use of a channeled ion implant, the desired range can be expected to be achieved at much lower implant energies. The implantation forms a damaged region 11a in substrate, to separate the substrate into the device layer 11 and the remainder 11b of the substrate. If the substrate is sufficiently thin, then the implantation to form the damaged region 11a may be conducted from the bottom of the substrate 11b.

Following the implantation, hydrophobic cleaning of the fabricated cell structure on Ge and the active-Si handle substrate is conduced. Specifically, the tunnel junction 6 and the bonding surface of active Si substrate 20 are cleaned. A typical, but not limiting process for this might include the following process steps:
a. Ultrasonic cleaning in acetone to remove particulates and organic contamination.
b. Ultrasonic cleaning in methanol to remove particulates and organic contamination.
c. Rinsing in DI water to remove methanol and acetone from steps a and b.
d. Brief etching in dilute hydrofluoric acid to remove any native oxide on the Si and GaAs substrates. Alternatively, hydrochloric acid or some other GaAs specific etchant may be necessary to leave a hydrophobic GaAs surface. This etch would be performed on the GaAs substrate only.
e. DI rinsing.
f. Spin drying to remove any water.

The process step leaves a clean, relatively hydrophobic surface on each substrate. Bonding can be initiated at this point, or subsequent surface activation with a dry process, such as plasma activation, can be performed to prepare the substrate surfaces for bonding. For plasma activation, process gases include, but are not limited to, N₂, forming gas (H₂/N₂), O₂, and Ar or He for low pressure plasma processes.

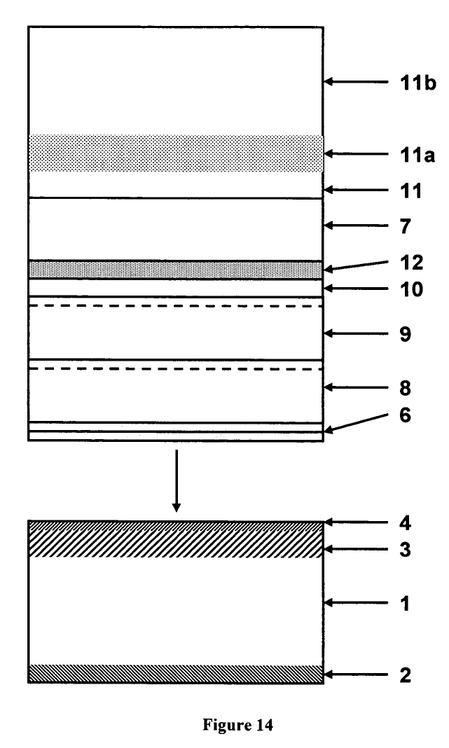

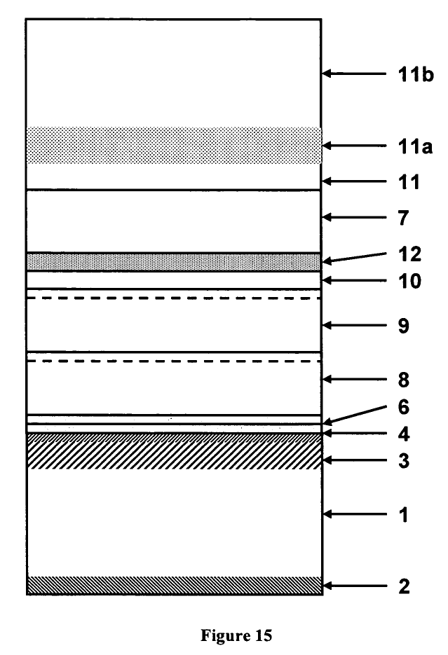

Bonding is initiated by placing the polished, activated substrate surfaces face-to-face and bringing them into contact, as shown in FIGS. 14 and 15. The region 4 of substrate 20 contacts the tunnel junction 6 to form a covalently bonded, low resistance interface. Several process parameters can be varied during this process to affect the quality of the bond, such as:
a. Bonding ambient, including but not limited to:
   i. Vacuum;
   ii. Low pressure gases such as H₂/N₂, N₂, Ar, etc.;
   iii. Atmospheric pressure gases such as H₂/N₂, N₂, Ar, etc.
b. Bond initiation temperature as a means of controlling the strain state of the bonded thin film.
c. Center-pin initiation to avoid the capture of gas at the bonded interface by near-simultaneous formation of multiple bonding points between the substrates.
d. Application of uniaxial pressure to ensure intimate contact between the substrates to improve bonding.

Following bond initiation, layer transfer is accomplished by annealing the substrate to enable the ion implantation induced exfoliation of the Ge layer 11, as shown in FIG. 15. This can be performed with a tailored temperature cycle to ensure optimal bonding and transfer uniformity. Additionally, the application of uniaxial pressure during the transfer process can be used to prevent thermo-mechanical stresses arising in the dissimilar substrate pair form causing debonding or fracture of the bonded pair prior to layer transfer.

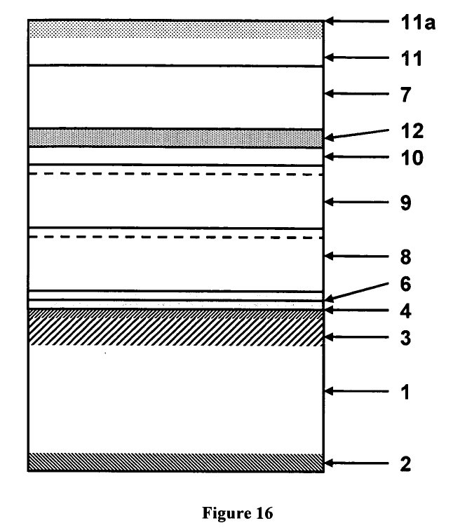

A material selective chemical mechanical polishing or chemical polishing can be used to remove the Ge layer 11 from the GaInP/GaAs wafer bonded tandem structure, as shown in FIG. 16. The literature reports that modest etch rates can be achieved for germanium using a 30% H₂O₂:H₂O etch composition. This etch forms a stable oxide on GaAs surfaces that prevents further etching. This can be used to remove the residual Ge from the GaAs device film. As described above with respect to the second embodiment, further refinement of the device layer thickness can be performed by building in an etch stop layer 12 structure using AlGaAs or GaInP.

In an alternative aspect of the third embodiment, the implant and the damaged layer may be omitted and the substrate 11 is removed by polishing or etching. In another alternative aspect of the third embodiment, the implant and the damaged layer may be omitted and the substrate 11 and buffer layer 7 are removed by a selective lateral etch of the etch stop layer 12 to separate the substrate 11 from the solar cell.

Backside Strain or Bow Minimization Layer of the Fourth Embodiment

The fourth embodiment describes providing a backside film to control the bow or stress in the bonded substrates, such as Ge/Si or GaAs/Si substrates or other substrates described above. The film is formed on the back side of the silicon substrate of the silicon cell 20. However, the film may be used with other Ge/Si substrates that are not part of a GaInP/GaAs/Si triple junction solar cell. Any suitable back side film which compensates for the strain in the bonded substrate may be used, such as a metal silicide film. Other suitable films, such as insulating films with a coefficient of thermal expansion greater than that of silicon may be used. The film preferably has the following properties.

The film is compatible with MOCVD processing environments of at least 700° C. in reactive process gases, with no significant outgassing, no film relaxation and no contamination of the grown epitaxial film. The film is either electrically conductive or removable via an etch process to allow access to the back surface of the cell structure to enable electrical contact. The film minimizes bow at the MOCVD growth temperature to prevent or reduce fabrication defects in the finished cell. The target bow for this application would be less than 25 μm. The film is integrated in such a way or with such a strain at low temperature (<50° C.), that there is minimal bow of the bonded structure to minimize the complication of a chemical mechanical planarization process. Acceptable bows in this range are typically 2 μm per inch or 8 μm for a 100 mm substrate. The backside thin film minimizes stress in the Ge thin film and in the subsequently grown GaInP/GaAs solar cell structure. In this way, plastic deformation and/or cracking of the GaAs thin film can be avoided.

In one aspect of the fourth embodiment, an electrically insulating film a coefficient of thermal expansion greater than that of silicon is used as the strain compensating film. The following processes describe the use of an insulating film on the back surface of the Si substrate 1.

The process starts with coating, such as spin coating, of the bonding surface of a Si handle substrate 1 with a protective layer. This protective layer may include photoresist or spin-on-glass. The glass requires an additional process step of densification following the deposition. Alternatively, a sputter or PECVD deposited oxide could be used to protect the bonding surface. The substrate 1 may already be implanted with regions 2, 3 and 4.

This is followed by deposition by a low temperature PECVD or other low temperature deposition method of an insulating film 13 on the back surface of the Si handle substrate 1. By varying the power cycle, pressure and precursors, the strain in the deposited film can be controlled at room temperature to ±100 MPa of normal stress. The thickness of the film is selected to minimize either bow or stress at the growth temperature to avoid bow-induced fabrication defects or stress-induced cracking, respectively. If desired, medium temperature PECVD may be used to deposit film 13. In this case, the glass or other medium temperature resistant material is used as the protective layer.

This is followed by a removal of the protective photoresist or spin-on-glass bonding surface protective layer. For photoresist, an organic solvent, such as acetone, may be used. For spin-on-glass, a hydrofluoric acid etch may be used.

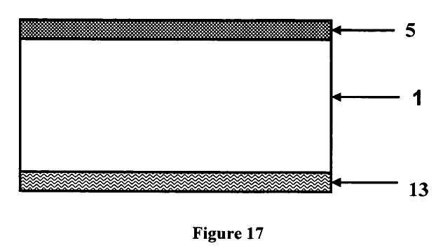

This is followed by the bonding of the device substrate and exfoliation of the bonded, transferred layer 5, such as a Ge layer, on the substrate 1. The resulting structure is shown in FIG. 17. The exfoliation step is followed by the damage removal from the thin film 5 using a chemical etch or a CMP process. Then, the GaInP/GaAs cell structure 9, 8 is epitaxially grown on layer 5 using MOCVD, MBE or other suitable method at an elevated temperature.

After the growth of the GaInP/GaAs structure, the backside layer 13 is removed for the fabrication of electrical contacts to the back surface of the substrate 1. This can be performed by a dry plasma etch using CF₄/O₂/N₂ gas mixtures.

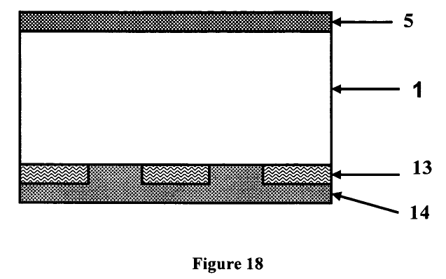

Alternatively, rather than removing the entire film 13 on the substrate 1, metallization lines can be lithographically defined and etched in the film 13, as shown in FIG. 18. Depending upon the stress state at room temperature following growth and the metal contact scheme, this could be an effective way to retain some of the bow minimization benefits of the film 13 during normal operation of the solar cell without a strong effect on the performance of the finished device structure.

The method of forming the structure of FIG. 18 is the same as the method of forming the structure of FIG. 17, except that rather than removing the entire film 13, openings to region 2 in substrate 1 are photolithographically formed in film 13 and then the metallization (i.e., metal contact(s)) 14 is formed in the openings to contact region 2 in substrate 1. The photolithography may be performed to define contact lines for the back substrate surface contact by spinning the photoresist on the back surface of the structure, performing photolithography of contact features in the photoresist, developing and baking of the photoresist, and selectively etching of the backside film 13 in the line pattern using the patterned resist as a mask. Then, the metallization 14 is formed on the back surface of substrate 1 to contact region 2. The residual metal can either be removed or remain as a current spreading film to reduce current collection loss.

In an alternative aspect of the fourth embodiment, a stable metal silicide film is used instead of the insulating film to create the electrical conducting backside strain or bow compensation film 13. This process involves a deposition of any one of a number of stable metal silicides, such as molybdenum silicide or titanium silicide (TiSi₂), at a controlled strain state to minimize the substrate bow. Following protection of the front surface of the substrate 1, the metal layer could be deposited either as a silicide alloy using sputter deposition or as a sputter deposited thin metal film, such as a molybdenum film. A subsequent anneal process leads to the alloying of the silicide layer and formation of a stable compound that will provide a counter-acting force to the Ge or GaAs thin film 5 on the front surface of the substrate 1. For example, a molybdenum silicide layer 13 may be deposited on the substrate 1 or a molybdenum layer is deposited on the substrate 1 and then reacted with the substrate 1 to form a molybdenum silicide layer 13. It is believed that in the incorporation of the metal film into a silicide alloy there will be stress relaxation. Thus, the alloy temperature will control the bow profile for the Ge/Si substrate. However, by depositing a sputtered silicide at a selected temperature this complication can be avoided. Following fabrication of a GaInP/GaAs cell structure on a Ge/Si/silicide virtual substrate, back-surface contact is dramatically easier for integrating the solar cell structure into a circuit. The conductive silicide film 13 does not have to be removed from the solar cell, and the metallization 14 may be formed on the conductive film 13 to make a low resistance contact to the substrate 1. The terms film and layer are used herein interchangeably.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents. All patent applications mentioned herein are incorporated by reference in their entirety.

What is claimed is:

1. A multi-junction solar cell, comprising:
a silicon solar subcell;
a GaInP solar subcell; and
a GaAs solar subcell located between the silicon solar subcell and the GaInP solar subcell, wherein the GaAs solar subcell is bonded to the silicon solar subcell such that a bonded interface exists between these subcells.

2. The solar cell of claim 1, wherein a low resistance contact exists between the GaAs solar subcell and silicon solar subcell.

3. The solar cell of claim 1, further comprising a bonded transferred first layer located between the silicon solar subcell and the GaAs solar subcell, wherein the bonded interface is located between the first layer and the silicon solar subcell and wherein the GaAs solar subcell is epitaxially grown over the first layer.

4. The solar cell of claim 3, wherein the first layer comprises a Ge layer.

5. The solar cell of claim 3, wherein the first layer comprises a GaAs layer.

6. The solar cell of claim 3, further comprising a tunnel junction located between the first layer and the GaAs solar subcell.

7. The solar cell of claim 1, further comprising a silicide strain compensation layer located on a bottom side of the silicon solar subcell.

8. A method of making a multi-junction solar cell, comprising:
implanting ions into a single crystal device substrate such that a damaged region is formed in the device substrate;
bonding the device substrate to an active silicon substrate comprising a silicon solar subcell;
separating at least a portion of the device substrate along the damaged region to leave a transferred layer bonded to the active silicon substrate; and
epitaxially forming at least one III-V semiconductor solar subcell on the transferred layer.

9. The method of claim 8, wherein the step of epitaxially forming at least one III-V semiconductor solar subcell on the transferred layer comprises epitaxially forming a GaAs solar subcell on the bonded transferred layer and epitaxially forming a GaInP solar subcell on the GaAs solar subcell.

10. The method of claim 9, wherein the device substrate comprises a Ge substrate and the transferred bonded layer comprises a Ge layer.

11. The method of claim 9, wherein the device substrate comprises a GaAs substrate or a GaAs layer formed on a Ge substrate and the transferred bonded layer comprises a GaAs layer.

12. The method of claim 9, further comprising forming a tunnel junction and a buffer layer on the transferred bonded layer prior to forming the GaAs subcell.

13. The method of claim 9, further comprising hydrophobically passivating the active silicon substrate and the device substrate bonding surfaces to form a low resistance contact between the silicon subcell and the GaAs subcell.

14. The method of claim 9, further comprising forming a strain compensating silicide layer on a bottom surface of the active silicon substrate prior to epitaxial growth of the GaAs subcell.

15. A method of making a multi-junction solar cell, comprising:
epitaxially forming a GaInP subcell over a device substrate;
epitaxially forming a GaAs solar subcell over the GaInP subcell;
bonding the GaAs subcell to an active silicon substrate comprising a silicon subcell; and
removing the device substrate from the solar cell.

16. The method of claim 15, wherein the step of removing the device substrate comprises:
implanting ions into the device substrate such that a damaged region is formed in the device substrate; and
separating at least a portion of the device substrate along the damaged region to leave a remnant layer over the GaInP subcell; and
removing the remnant layer.

17. The method of claim 15, further comprising forming a sacrificial layer between the device substrate and the GaInP cell, such that the step of removing the device substrate comprises laterally etching the sacrificial layer to separate the device substrate and the GaInP cell.

18. The method of claim 15, wherein the device substrate comprises a Ge substrate.

19. The method of claim 15, further comprising forming a tunnel junction on the GaAs subcell prior to the step of bonding.

20. The method of claim 15, further comprising hydrophobically passivating the active silicon substrate and the bonding surface over the GaAs subcell to form a low resistance contact between the silicon subcell and the GaAs subcell.
